(19) United States
(12) Patent Application Publication
(10) Pub. No.: US 2008/0121982 A1
(43) Pub. Date: May 29, 2008

(54) Semiconductor structure, semiconductor memory device and method of manufacturing the same

(76) Inventor: Hocine Boubekeur, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/505,494

(22) Filed: Aug. 17, 2006

(51) Int. Cl. H01L 23/532; H01L 21/768; H01L 27/115; H01L 21/8247

(52) U.S. Cl. 257/324; 257/776; 257/769; 438/622; 257/E23.157; 257/E21.575

(57) ABSTRACT

A semiconductor structure includes first and second conductive lines which cross each other. The second conductive lines are electrically insulated from the first conductive lines via an insulating material. The second conductive lines include first and second sections. First sections are arranged beneath crossing first conductive lines and include a semiconductor material. The second sections are disposed between adjacent first conductive lines and include a metal-semiconductor compound. A method of manufacturing a semiconductor structure involves forming initial second conductive lines, forming first conductive lines and providing a metal-semiconductor compound on an exposed surface of the initial second conductive lines, thereby obtaining second conductive lines. Forming the metal-semiconductor compound is performed after forming the first conductive lines.

### FIELD THE INVENTION

The invention relates to a semiconductor structure, a semiconductor memory device and a method of manufacturing the same.

### BACKGROUND

Semiconductor structures, for example memory cell arrays, comprise conductive lines. In order to achieve good performance of the semiconductor structure, the resistance of the conductive lines has to be low. One attempt to achieve good performance of the semiconductor structure is to use materials with a small specific resistivity. Not all materials may be used in a semiconductor structure, since some materials cause unwanted phenomena in the semiconductor structure. Therefore metal-semiconductor compounds, like for instance silicides, are used.

A problem of using a metal-semiconductor compound for conductive lines, which are formed beneath other conductive lines, arises from the fact, that metal-semiconductor compounds do not withstand high thermal budgets. Holes within the metal-semiconductor compound or even destruction of the metal-semiconductor compound may appear resulting in an increase of the resistance of the conductive lines or even in destruction of the conductive lines. High thermal budgets may be caused by process steps, which are subsequently performed after forming first conductive lines comprising the metal-semiconductor compound in order to form second conductive lines above the first conductive lines.

In nitride read only memory (NROM) technology, buried conductive lines are used as bitlines in the memory cell array. FIG. 1 shows a top view on a NROM memory cell array. Buried bitlines 8 and wordlines 7 which extend at right angles to bitlines 8 define a lattice structure. Respective memory cells 1 are arranged below wordlines 7 between two respective bitlines 8. Two memory cells 1 are shown by way of example by dashed lines in FIG. 1. Below the wordlines gate regions are provided, whereas the diffusion regions of the bitlines define the source/drain regions of a respective cell. Wordlines 7 and gate regions of single cells are separated from each other by an insulating layer 9.

FIG. 2 shows a cross-sectional view of the NROM cell array along line I-I as is shown in FIG. 1, for example. Line I-I extends along a wordline 7. In particular, two NROM cells 1 are completely shown. NROM cell 1 is an n-channel MOSFET device, wherein the gate dielectric is replaced with a storage layer stack 27. As is shown in FIG. 2, storage layer stack 27 is disposed above channel 25 and under gate electrode 26. Channel 25 is arranged between two adjacent doped regions 2 forming bitlines 8. Storage layer stack 27 usually comprises a charge trapping layer 272, which may, for example, be a silicon nitride layer. A lower boundary layer 271 is disposed beneath the charge trapping layer. An upper boundary layer 273 is disposed above the charge trapping layer. The charge trapping layer 272 is disposed between the upper and lower boundary layers. Upper and lower boundary layers 271, 273 have a thickness larger than 2 nm to avoid any direct tunnelling. The memory cell is programmed by charge transport from channel 25 into charge trapping layer 272 by tunneling through lower boundary layer 271 and erased by charge transport from charge trapping layer 272 into channel 25 by tunnelling through lower boundary layer 271. Gate electrode 26 may be formed of a semiconductor material, as for instance polysilicon. Separate gate electrodes 26 are connected by wordline 7, formed by a polysilicon layer 12, a metal layer 11 and a cap layer 10. A charge stored in storage layer stack 27 determines the threshold voltage of the transistor. Accordingly, a charge trapped in storage layer stack 27 can be detected by applying corresponding voltages to doped regions 2 and gate electrode 26.

In regions between two memory cells 1, an insulating layer 9 electrically insulates bitlines 8 from wordline 7.

A structure having buried bitlines, like for instance the NROM cell array of FIG. 1, shows a limited conductivity of doped regions 2 forming bitlines 8.

### SUMMARY

The invention provides a semiconductor structure comprising a plurality of first conductive lines disposed along a first direction and a plurality of second conductive lines disposed along a second direction. The second direction is different from the first direction and the second conductive lines are formed beneath the first conductive lines. The second conductive lines are electrically insulated from the first conductive lines by an insulating material. At those portions of the second conductive lines, where the first conductive lines do not pass the second conductive lines, the second conductive lines comprise a metal-semiconductor compound.

The invention provides a semiconductor memory device comprising a semiconductor substrate, a plurality of first conductive lines, a plurality of second conductive lines and a plurality of memory cells. The first conductive lines are disposed along a first direction and the second conductive lines are disposed along a second direction being different from the first direction. The second conductive lines are formed beneath the first conductive lines and are electrically insulated from the first conductive lines by an insulating material. The second conductive lines comprise first and second portions. The first portions comprise a semiconductor material, while the second portions comprise a metal-semiconductor compound. The first conductive lines cover the first portions of the second conductive lines. The memory cells are formed at least partially in the semiconductor substrate and form a memory cell array. Each memory cell of the memory cell array may be addressed by at least one first conductive line and at least one second conductive line.

Furthermore the invention provides a method of manufacturing a semiconductor structure. First a plurality of second initial conductive lines disposed along a second direction is formed, wherein the initial second conductive lines comprise a semiconductor material.

Subsequently, a plurality of first conductive lines disposed along a first direction being different from the second direction is formed. The first conductive lines are electrically insulated from the second initial conductive lines by an insulating material.

A metal-semiconductor compound is provided on an exposed surface of the initial second conductive lines, thereby obtaining second conductive lines. This processing step is carried out after forming the first conductive lines.

According to another embodiment of the invention, a method of manufacturing a semiconductor memory device comprises providing a semiconductor substrate including a surface, forming a plurality of semiconductor memory cells, forming a plurality of initial second conductive lines, forming a plurality of first conductive lines, and providing a metal-semiconductor compound.

The memory cells are formed at least partially in the semiconductor substrate and form a memory cell array.

The initial second conductive lines are disposed along a second direction and comprise a semiconductor material.

The first conductive lines are disposed along a first direction being different from the second direction. The first conductive lines are electrically insulated from the initial second conductive lines by an insulating material. Each memory cell may be addressed by at least one first conductive line and at least one second conductive line.

The metal-semiconductor compound is provided on an exposed surface of the initial second conductive lines after forming the first conductive lines. Thereby second conductive lines are obtained.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with a description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

The invention is explained in more detail below with reference to exemplary embodiments, where:

FIG. 1 illustrates a plan view on an exemplary semiconductor structure;

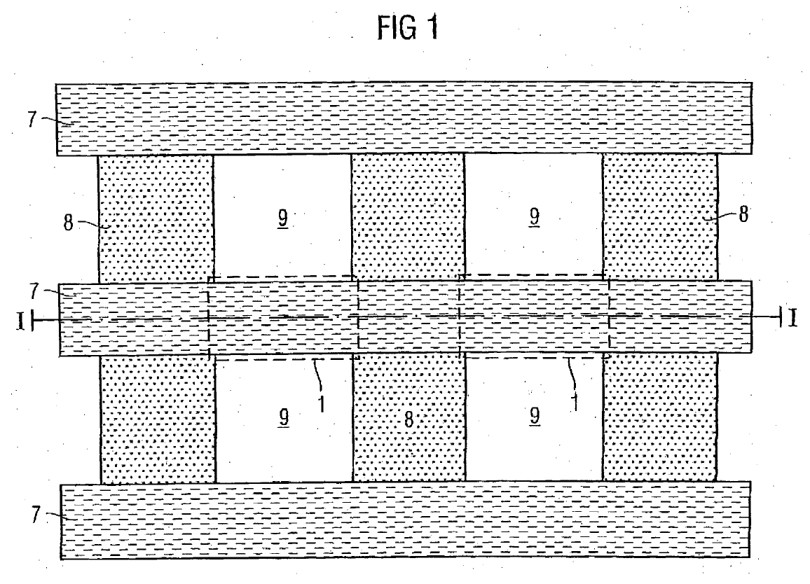

FIG. 2 illustrates a schematic cross-section of the semiconductor structure of FIG. 1 along the line I-I;

FIG. 3 illustrates a plan view on a semiconductor structure according to the invention;

FIG. 4 illustrates a schematic cross-section of the semiconductor structure of FIG. 1 along the line II-II;

FIG. 5 illustrates a schematic cross-section of the semiconductor structure of FIG. 1 along the line III-III;

FIG. 6 illustrates a schematic cross-section of the semiconductor structure of FIG. 1 along the line II-II at a first process;

FIG. 7 illustrates a schematic cross-section of the semiconductor structure of FIG. 1 along the line III-III at the first process;

FIG. 8 illustrates a schematic cross-section of the semiconductor structure of FIG. 1 along the line II-II at a second process;

FIG. 9 illustrates a schematic cross-section of the semiconductor structure of FIG. 1 along the line III-III at the second process;

FIG. 10 illustrates a schematic cross-section of the semiconductor structure of FIG. 1 along the line II-II at a third process;

FIG. 11 illustrates a schematic cross-section of the semiconductor structure of FIG. 1 along the line III-III at the third process;

FIG. 12 illustrates a schematic cross-section of the semiconductor structure of FIG. 1 along the line II-II at a fourth process;

FIG. 13 illustrates a schematic cross-section of the semiconductor structure of FIG. 1 along the line III-III at the fourth process.

### DETAILED DESCRIPTION

In the following detailed description, reference is made to the accompanying drawings, which form a part hereof, and in which is shown by way of illustration specific embodiments by which the invention may be practiced. In this regard directional terminology, such as “top”, “bottom”, “front”, “back”, “leading”, “trailing”, etc. is used with reference to the orientation of the figures being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the dependent claims.

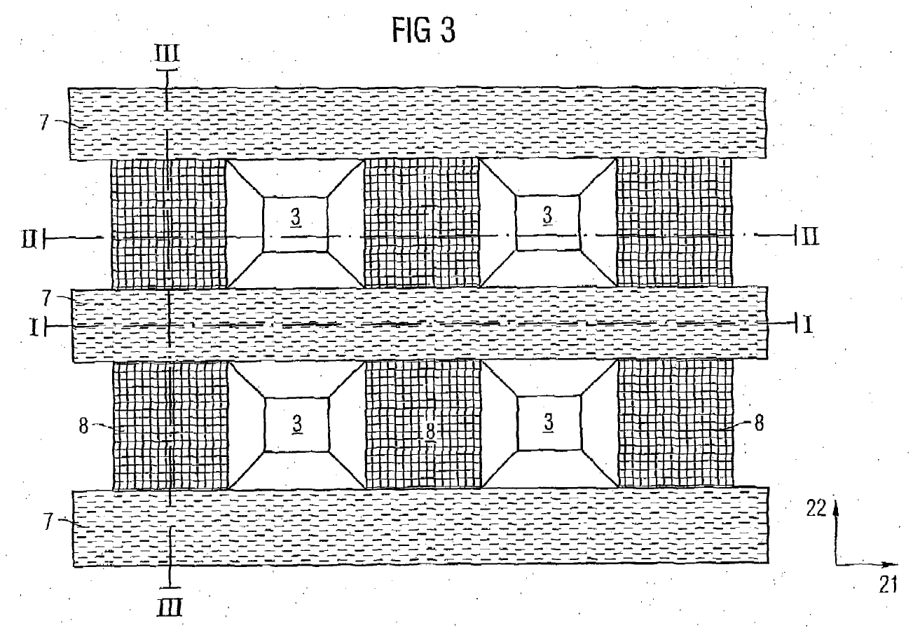

FIG. 3 illustrates a schematic plan view on an embodiment of the semiconductor structure of the invention. It shows by way of example an array of NROM memory cells with a plurality of first conductive lines 7 and a plurality of second conductive lines 8. Conductive lines 7 may be wordlines of the memory cell array, and conductive lines 8 may be bitlines of the memory cell array. Nevertheless, any other semiconductor structure with at least two pluralities of conductive lines lies in the scope of the invention.

As shown in FIG. 3, second conductive lines 8 lie beneath first conductive lines 7. Conductive lines 7 run along a first direction 21, while conductive lines 8 run along a second direction 22 which is different from the first direction. The second direction 22 may be perpendicular to the first direction 21 as shown in FIG. 3.

First and second conductive lines are electrically insulated from each other by an insulating layer (not shown in FIG. 3). In the embodiment shown in FIG. 3, self aligned isolation trenches 3 electrically insulate different conductive lines 8 from each other. Layers that may be formed within isolation trenches 3 are not shown in FIG. 3. Nevertheless, other insulation structures may be formed.

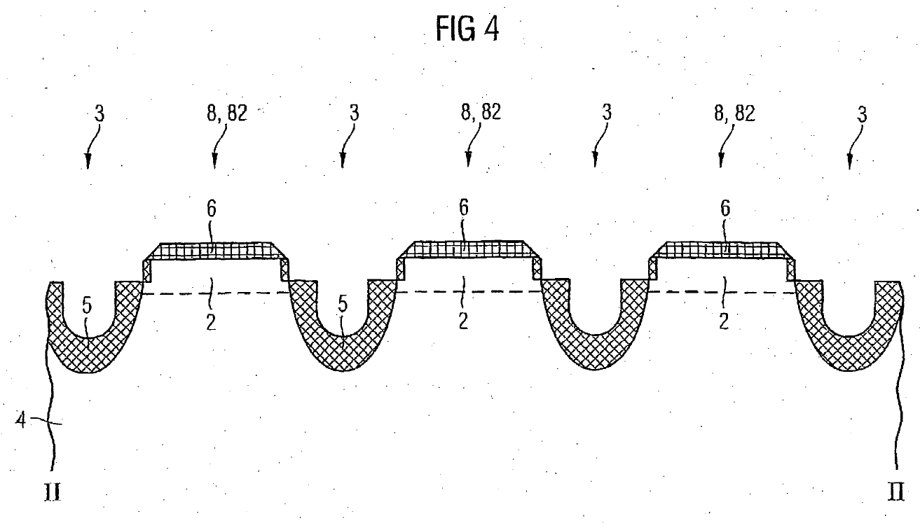

FIG. 4 illustrates a schematic cross section of the embodiment of the semiconductor structure of FIG. 3 along line II-II. Line II-II extends along first direction 21 between two neighboring conductive lines 7 thereby crossing different conductive lines 8. In a semiconductor substrate 4, by way of example p-silicon, second conductive lines 8 are formed. Conductive lines 8 comprise first and second portions 81 and 82. In second portions 82 shown in FIG. 4, each conductive line 8 comprises a doped region 2, by way of example n-doped silicon, formed within semiconductor substrate 4 and a metal-semiconductor compound 6 which is formed on top of doped region 2. Metal-semiconductor compound 6 may be formed also at the sidewalls of doped region 2 so as to cover the sidewalls partially, as shown in FIG. 4. In the case where semiconductor substrate 4 is formed of silicon, the metal-semiconductor compound 6 is a silicide.

In semiconductor substrate 4 isolation trenches 3 are formed. They electrically insulate adjacent second conductive lines 8 from each other. A covering layer 5 is formed at the surface of isolation trenches 3. Covering layer 5 may cover the surface of isolation trenches 3 only partially or may completely fill isolation trenches 3. Covering layer 5 may be an insulating layer or a layer stack comprising an insulating layer.

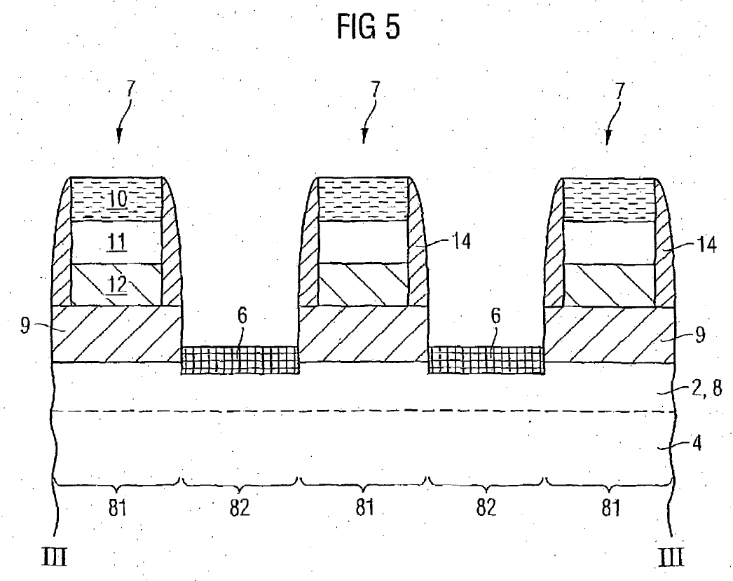

FIG. 5 illustrates a schematic cross section of the embodiment of the semiconductor structure of FIG. 3 along line III-III. Line III-III extends along second direction 22 along a conductive line 8. First conductive lines 7 are formed above a second conductive line 8 formed in semiconductor substrate 4. First conductive lines 7 may be formed by a layer stack as shown in FIG. 3. By way of example, conductive lines 7 comprise a semiconductor layer 12, a metal layer 11 and a cap layer 10. Semiconductor layer 12 may for instance be a poly-silicon layer. Metal layer 11 may for instance be W or WSiₓ or any other layer of a material with low resistivity. Cap layer 10 may for instance be a nitride layer. At the sidewalls of each first conductive line 7 an insulating layer 14 is formed. Insulating layer 14 may be a silicon oxide or nitride or of any other conventionally used spacer material. Nevertheless, conductive lines 7 may be formed of any other conductive material.

Conductive lines 7 are electrically insulated from conductive lines 8 by insulating layer 9 in portions 81. Portions 81 are that portions where conductive lines 7 pass conductive lines 8. Insulating layer 9 may be a silicon oxide, for instance formed by a CVD method using TEOS (Tetra-ethyl-ortho-silicate) as a starting material, and may have a thickness of several nanometers.

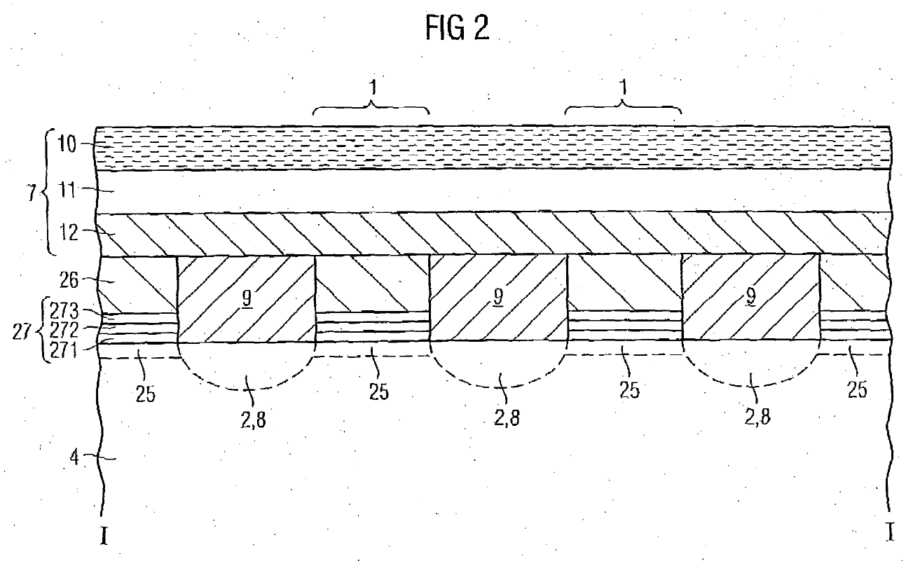

In the NROM cell array shown in FIG. 3, memory cells are formed beneath conductive lines 7 between two neighboring conductive lines 8. The schematic cross section of memory cell array along line I-I in FIG. 3 along a conductive line 7 is identical with the cross section shown in FIG. 2 and has been explained above.

Nevertheless, other semiconductor structures are possible, wherein first conductive lines 7 are formed above second conductive lines 8 and wherein other memory cell arrays or no memory cells at all are formed. In any way, first and second conductive lines are electrically insulated from each other by an insulating layer.

According to the invention, conductive line 8 comprises first and second portions 81 and 82. In first portions 81, where first conductive lines 7 pass (cover) second conductive line 8; second conductive line 8 comprises a semiconductor material. In second portions 82, where first conductive lines 7 do not pass second conductive line 8, second conductive line 8 comprises a semiconductor-metal compound. In the embodiment shown in FIGS. 3 and 5, all sections of conductive line 8 comprise a doped region 2 formed within semiconductor substrate 4. Metal-semiconductor compound 6 is formed on top of doped region 2 only in second sections 82 of conductive line 8 which are not covered by first conductive lines 7 or insulating layer 14.

According to the invention, the resistance of second conductive lines 8 is reduced with reference to conventionally used second conductive lines. Since second sections 82 of conductive lines 8 according to the invention comprise metal-semiconductor compound 6, conductive lines 8 show a lower resistance compared to conductive lines without a metal-semiconductor compound.

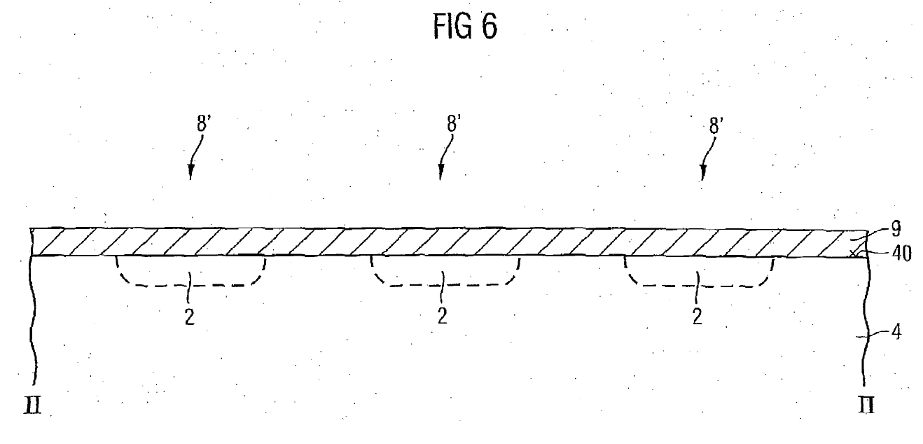

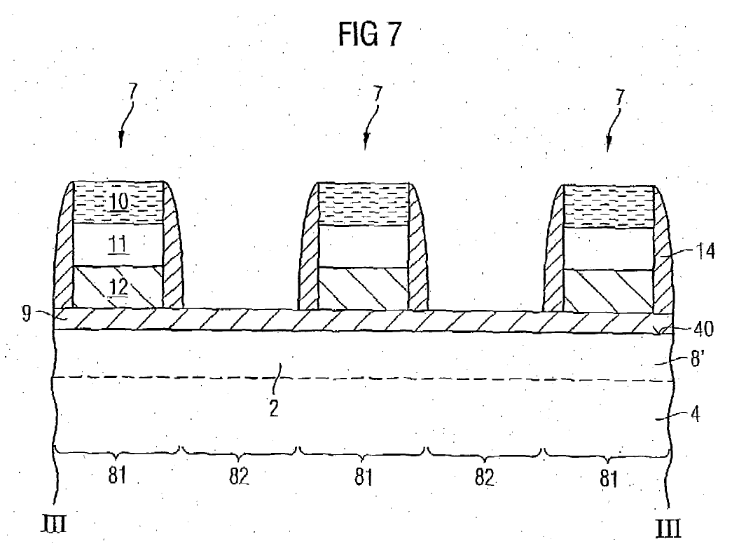

A method of manufacturing a semiconductor structure according to the invention is explained with reference to FIGS. 6 to 13. FIGS. 6, 8, 10, and 12 show schematic cross-sectional views of the semiconductor structure of FIG. 3 at different processing steps along the line II-II. FIGS. 7, 9, 11, and 13 show schematic cross-sectional views of the semiconductor structure of FIG. 3 at different processing steps along the line III-III.

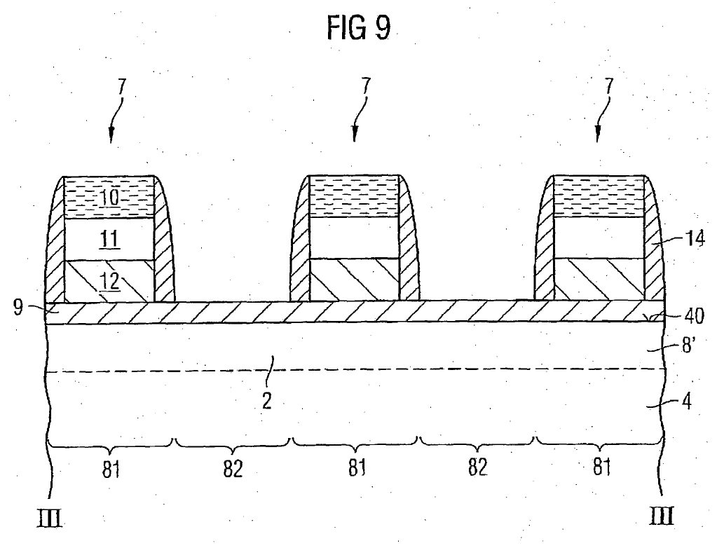

First, doped regions 2, insulating layer 9, gate regions comprising storage layer stack 27 and gate electrode 26, and first conductive lines 7 are formed. These processing steps are not shown in any figure, since they are known by any person skilled in the art. The resulting structure is shown in FIGS. 6 and 7. Doped regions 2 are formed within semiconductor substrate 4. Regions 2 are formed as single lines extending from the surface 40 of substrate 4 into a predetermined depth, thereby forming initial second conductive lines 8′ which extend above sections 81 and 82, as shown in FIG. 7. Insulating layer 9 is formed on surface 40 of substrate 4 except the gate regions (not shown in FIGS. 6 and 7). First conductive lines 7 are formed above doped regions 2 and insulating layer 9, and above the gate regions. Insulating layer 14 is formed at the sidewalls of first conductive lines 7. In the case, that forming first conductive lines 7 comprises an etching step, the thickness of that portions of insulating layer 9 which are not covered by conductive line 7 or insulating layer 14 may be smaller than the thickness of covered portions of insulating layer 9 caused by over etching. This is not shown in FIGS. 7 and 9.

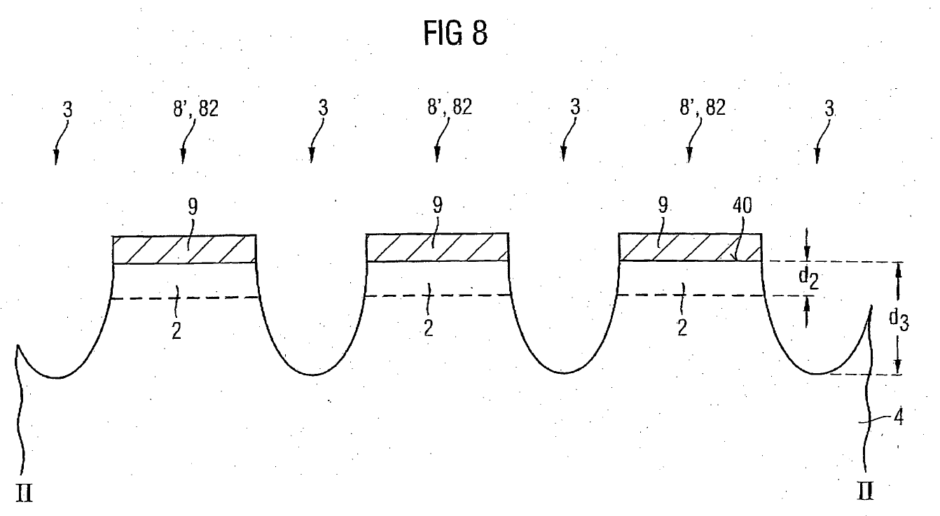

FIGS. 8 and 9 show the semiconductor structure at a first process following above mentioned processing. Insulating layer 9 is patterned such that it is preserved only above doped regions 2. It serves as a mask for forming isolation trenches 3 within surface 40 of substrate 4. Isolation trenches 3 extend to a predetermined depth d3 into substrate 4, wherein the depth d3 is larger than the depth d2 of doped regions 2. Depth d3 and depth d2 are measured from surface 40 of substrate 4. The resulting structure is shown in FIGS. 8 and 9 wherein FIG. 8 shows a cross-sectional view along first direction 21 in the region between two neighboring conductive lines 7 and FIG. 9 shows a cross-sectional view along a conductive line 8. As can be seen, FIG. 9 is identical with FIG. 7 since insulating layer 9 remains above doped regions 2.

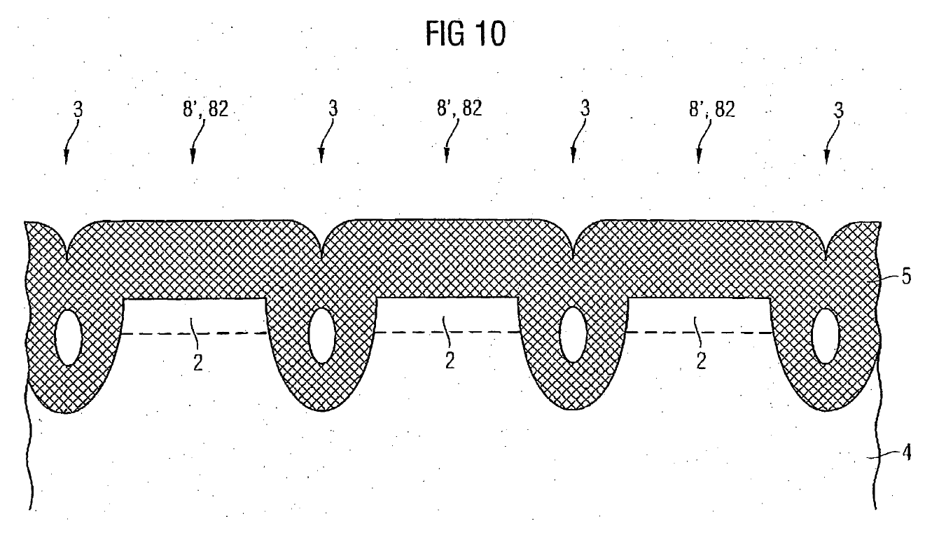

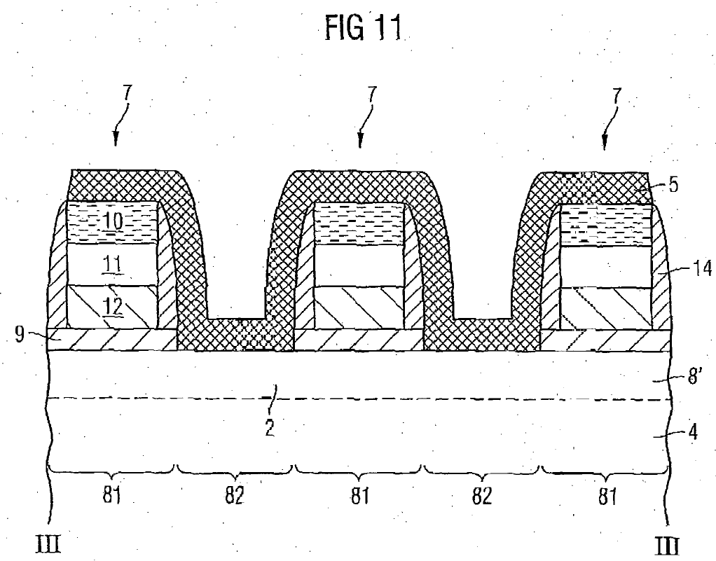

Next, insulating layer 9 is removed from top of doped regions 2. Subsequently, a covering layer 5 is formed on top of the surface of the semiconductor structure. Layer 5 may be an insulating layer as for instance silicon oxide or any other layer which prevents forming a silicide with substrate 4 at following processing steps. The resulting structure is shown in FIGS. 10 and 11. As shown in FIG. 10, covering layer 5 covers the surface of doped regions 2 and the surface of isolation trenches 3. It is not necessary to fill isolation trenches 3 completely with layer 5. Holes in covering layer 5, as shown in FIG. 10, do not affect further processing of semiconductor structure. As shown in FIG. 11, covering layer 5 also covers the surface of first conductive lines 7 and insulating layer 14.

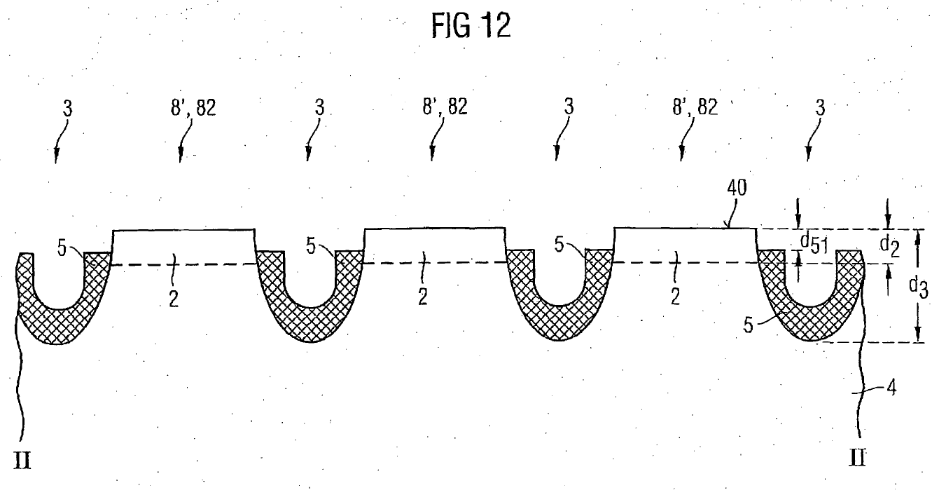

Subsequently, layer 5 is removed from top of doped regions 2 leaving the surface of isolation trenches 3 at least partially covered. Consequently, layer 5 has to cover at least those portions of the surface of isolations trenches 3 which are not adjacent to doped regions 2, as shown in FIG. 12. In other words, layer 5 extends from a depth d51 to depth d3 on the surface of isolation trench 3. Depth d51 has to be smaller than depth d2 which is the depth of doped region 2 extending into substrate 4. Depth d3 is the depth of isolation trenches 3. Depths d2, d3, and d51 are measured from surface 40 of substrate 4.

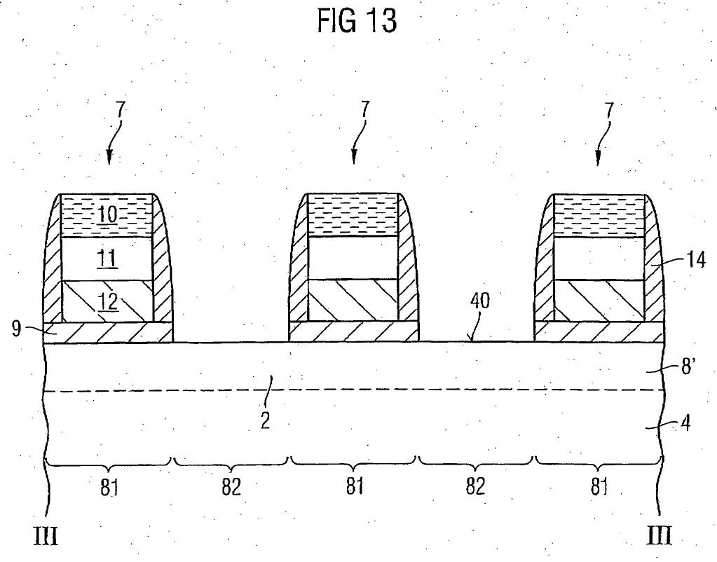

Removing of layer 5 from top of doped regions 2 may be carried out by an anisotropic recess etching. The depth d51 can be selected arbitrarily as long as d51 is smaller than d2 and as long as layer 5 is fully removed from top of doped regions 2. The resulting structure is shown in FIGS. 12 and 13. As shown in FIG. 12, the top and a part of the sidewalls, of doped regions 2, is not covered by layer 5. As shown in FIG. 13, insulating layer 5 is removed from first conductive lines 7 and insulating layer 14. Nevertheless, insulating layer 5 may remain on first conductive lines 7 by using a mask.

In a next process, a metal-semiconductor compound 6 is formed on those portions of the surface of doped regions 2, which are not covered by first conductive lines 7 or layers 5 or 14. Thus, second conductive lines 8 comprising first and second sections 81 and 82 according to the invention are obtained. The resulting structure is shown in FIGS. 3 to 5. As shown in FIG. 4, metal-semiconductor compound 6 covers the top and partially the sidewalls of doped regions 2 in sections 82.

Isolation trenches 3 may be filled with an insulating material in a later process step, wherein layer 5 may remain at the surface of isolation trenches 3. Nevertheless layer 5 may be removed from surface of isolation trenches 3 before filling isolation trenches 3.

Forming of metal-semiconductor compound 6 may be carried out by depositing a metal layer on the surface of the semiconductor structure and carrying out a temperature process. Thus, metal-semiconductor compound 6 is formed only at those regions, where the metal layer contacts a semiconductor material, like for instance doped regions 2. Therefore, the surface of isolation trenches 3 adjoining substrate 4 have to be covered by covering layer 5. While forming metal-semiconductor compound that way, material of doped regions 2 is partially transformed. Therefore, metal-semiconductor compound 6 extends partially into doped region 2, as shown in FIG. 3. In other words, the lower interface, between metal-semiconductor compound 6 and doped region 2, lies beneath surface 40 of substrate 4. Subsequently, the metal layer not being transformed into metal-semiconductor compound 6 is removed.

The metal layer may comprise: Co, W, Pt or Ni. The metal-semiconductor compound 6 may comprise: CoSiₓ, WSiₓ, PtSiₓ or NiSiₓ in case of silicon as the semiconductor material of substrate 4.

Nevertheless, other possibilities to form metal-semiconductor compound 6 being comprised by the semiconductor structure according to the invention are possible.

According to the invention, metal-semiconductor compound 6 is formed after forming first conductive line 7. Thus, problems, like deterioration or destruction of metal-semiconductor compounds, caused by high-temperature processes used to form conductive line 7 may be avoided, while reducing the resistance of second conductive lines 8.

The embodiments of the invention described in the foregoing are examples are given by way of illustration and the invention is in no ways limited thereto. Any modification, variation and equivalent arrangement should be considered as being included within the scope of the invention.

Although specific embodiments has been illustrated and described herein, it will be appreciated by those of ordinary skill in the art that a variety of alternate and/or equivalent implementations may be substituted for the specific embodiments shown and described without departing from the scope of the present invention. This application is intended to cover any adaptation or variations of the specific embodiments discussed herein. Therefore it is intended that this invention be limited only by the claims and the equivalents thereof.

### LIST OF REFERENCE SIGNS

1 memory cell
2 doped region
3 isolation trench
4 substrate
5 covering layer (may be oxide)
6 metal-semiconductor compound
7 first conductive lines
8 second conductive lines
8′ initial second conductive lines
9 insulating layer
10 cap layer (nitride)
11 metal layer
12 semiconductor layer
14 insulating layer (spacer)
21 first direction
22 second direction
25 channel
26 gate electrode (polysilicon)
27 storage layer stack
271 lower boundary layer
272 charge trapping layer
273 upper boundary layer
40 surface of the substrate
81 first section of second conductive line
82 second section of second conductive line
d2 depth of doped region
d3 depth of isolation trench
d51 depth of recessed covering layer

What is claimed is:

1. A semiconductor structure, comprising:
a plurality of first conductive lines disposed along a first direction; and
a plurality of second conductive lines disposed along a second direction, the second direction being different from the first direction such that the first conductive lines cross the second conductive lines, the second conductive lines being formed beneath the first conductive lines and being electrically insulated from the first conductive lines via an insulating material, wherein the second conductive lines comprise a metal-semiconductor compound along portions of the second conductive lines that the first conductive lines do not pass over.

2. The semiconductor structure of claim 1, wherein the first conductive lines are wordlines of a memory cell array, and wherein the second conductive lines are bitlines of the memory cell array.

3. The semiconductor structure of claim 1, wherein the second conductive lines further comprise silicon, and wherein the metal-semiconductor compound comprises a silicide.

4. The semiconductor structure of claim 3, wherein the silicide comprises at least one of: CoSiₓ, WSiₓ, PtSiₓ or NiSiₓ.

5. The semiconductor structure of claim 1, wherein the second conductive lines further comprise doped semiconductor regions of a semiconductor substrate.

6. The semiconductor structure of claim 5, further comprising isolation trenches formed between the second conductive lines.

7. A semiconductor structure, comprising:
a plurality of first conductive lines disposed along a first direction; and
a plurality of second conductive lines disposed along a second direction, the second direction being different from the first direction such that the first conductive lines cross the second conductive lines, the second conductive lines being formed beneath the first conductive lines and being electrically insulated from the first conductive lines via an insulating material;
wherein the second conductive lines comprise first and second portions, the first portions comprising a semiconductor material, the second portions comprising a metal-semiconductor compound, wherein the first portions are disposed beneath the first conductive lines.

8. A semiconductor memory device, comprising:
a semiconductor substrate;
a plurality of first conductive lines disposed along a first direction;
a plurality of second conductive lines disposed along a second direction, the second direction being different from the first direction such that the first conductive lines cross the second conductive lines, the second conductive lines being formed beneath the first conductive lines and being electrically insulated from the first conductive lines via an insulating material, wherein the second conductive lines comprise first and second portions, the first portions comprising a semiconductor material, the second portions comprising a metal-semiconductor compound, wherein the first portions are disposed beneath the first conductive lines; and
a plurality of semiconductor memory cells formed at least partially in the semiconductor substrate, the memory cells forming a memory cell array, wherein each memory cell is addressable via at least one first conductive line and at least one second conductive line.

9. The semiconductor memory device of claim 8, wherein the first conductive lines are wordlines of a memory cell array, and wherein the second conductive lines are bitlines of the memory cell array.

10. The semiconductor memory device of claim 8, wherein the memory cells are nitride read only memory (NROM) cells.

11. The semiconductor memory device of claim 8, wherein the second conductive lines comprise doped semiconductor regions of the semiconductor substrate.

12. The semiconductor memory device of claim 11, further comprising isolation trenches formed in portions of the semiconductor substrate that do not comprise second conductive lines or are not traversed by first conductive lines.

13. A semiconductor device, comprising:
a plurality of first conductive lines disposed along a first direction;
a plurality of second conductive lines disposed along a second direction, the second direction being different from the first direction such that the first conductive lines cross the second conductive lines, the second conductive lines being formed beneath the first conductive lines and being electrically insulated from the first conductive lines by an insulating material, wherein the second conductive lines comprise first and second portions, the first portions comprising a semiconductor material, the second portions comprising a metal-semiconductor compound, wherein the first conductive lines traverse the first portions of the second conductive lines; and
a plurality of components for storing information, wherein each component is addressable via at least one first conductive line and at least one second conductive line.

14. A method of manufacturing a semiconductor structure, comprising:
forming a plurality of initial second conductive lines disposed along a second direction, the initial second conductive lines comprising a semiconductor material;
forming a plurality of first conductive lines disposed along a first direction, the first direction being different from the second direction, wherein the first conductive lines are electrically insulated from the initial second conductive lines via an insulating material; and
subsequently forming a metal-semiconductor compound on an exposed surface of the initial second conductive lines, thereby obtaining second conductive lines.

15. The method of claim 14, wherein the initial second conductive lines comprise doped semiconductor regions of a semiconductor substrate.

16. The method of claim 15, further comprising:
forming isolation trenches within portions of a surface of the semiconductor substrate that do not comprise doped regions of initial second conductive lines and are not traversed by first conductive lines, the isolation trenches having a surface; and
forming a covering layer at the surface of the isolation trenches, leaving at least the top of the doped regions exposed, wherein the covering layer prevents a metal-semiconductor compound from being formed on the covered surface of the isolation trenches.

17. The method of claim 14, wherein forming a metal-semiconductor compound comprises:
depositing a metal layer on the exposed surface of the initial second conductive lines;
performing a temperature process to form the metal-semiconductor compound; and
removing the metal layer that is not transformed into the metal-semiconductor compound.

18. The method of claim 17, wherein the metal layer comprises at least one of:
Co, W, Pt, and Ni.

19. The method of claim 14, wherein the semiconductor material of the initial second conductive lines comprises silicon, and wherein the metal-semiconductor compound comprises a silicide.

20. The method of claim 19, wherein the silicide comprises at least one of: CoSiₓ, WSiₓ, PtSiₓ, and NiSiₓ.

21. A method of manufacturing a semiconductor memory device, comprising:
providing a semiconductor substrate including a surface;
forming a plurality of semiconductor memory cells at least partially in the semiconductor substrate, the memory cells forming a memory cell array;
forming a plurality of initial second conductive lines disposed along a second direction, the initial second conductive lines comprising a semiconductor material;
forming a plurality of first conductive lines disposed along a first direction, the first direction being different from the second direction, wherein the first conductive lines are electrically insulated from the initial second conductive lines via an insulating material, wherein each memory cell is addressable via at least one first conductive line and at least one second conductive line; and
subsequently providing a metal-semiconductor compound on an exposed surface of the initial second conductive lines, thereby obtaining second conductive lines.

22. The method of claim 21, wherein the initial second conductive lines comprise doped semiconductor regions of the semiconductor substrate.

23. The method of claim 22, further comprising:
forming isolation trenches within portions of the surface of the semiconductor substrate that do not comprise doped regions of initial second conductive lines and are not traversed by the first conductive lines, the isolation trenches having a surface; and
forming a covering layer at the surface of the isolation trenches, leaving at least the top of the doped regions exposed, wherein the covering layer prevents a metal-semiconductor compound from being formed on the covered surface of the isolation trenches.

24. The method of claim 21, wherein forming a metal-semiconductor compound comprises:
depositing a metal layer on the exposed surface of the initial second conductive lines;
performing a temperature process to form the metal-semiconductor compound; and
removing the metal layer that is not transformed into the metal-semiconductor compound.

25. The method of claim 24, wherein the metal layer comprises at least one of: Co, W, Pt, and Ni.

26. The method of claim 21, wherein the semiconductor material of the initial second conductive lines comprises silicon; and wherein the metal-semiconductor compound comprises a silicide.

27. The method of claim 26, wherein the silicide comprises at least one of: CoSiₓ, WSiₓ, PtSiₓ, and NiSiₓ.
